(19) United States
(12) Patent Application Publication
(10) Pub. No.: US 2018/0069210 A1
(43) Pub. Date: Mar. 8, 2018

(54) BATTERY PACK WITH CIRCUIT BOARD HAVING NESTED CASTELLATIONS FOR SUB-FLUSH POWER WIRE SOLDERING

(71) Applicant: Apple Inc., Cupertino, CA (US)

(72) Inventors: Nathan J. Bohney, Cupertino, CA (US); Todd L. Mumaw, Cupertino, CA (US)

(21) Appl. No.: 15/426,395

(22) Filed: Feb. 7, 2017

Related U.S. Application Data
(60) Provisional application No. 62/383,789, filed on Sep. 6, 2016.

(51) Int. Cl. H01M 2/10; H05K 1/09; H05K 1/11; H05K 1/18; H01M 2/20; H01M 10/42

(52) U.S. Cl. CPC H01M 2/1055; H05K 1/09; H05K 1/115; H05K 1/117; H05K 1/181; H01M 2/204; H01M 2220/30; H05K 2201/09009; H05K 2201/10037; H05K 2201/10151; H05K 2201/10295; H05K 2201/10522; H05K 2201/10583; H01M 10/425

(57) ABSTRACT

A streamlined battery pack can contain at least two battery cells. A printed circuit board (PCB) of the battery pack can include a protection control module. The PCB can have castellations along its perimeter in which wires are soldered. The wires can include battery power wires and battery monitoring signal wires. The castellations are sized so that the egress wires can be soldered therein without substantially protruding from the outline of the PCB. The PCB has a surface area that is no greater than an end of the battery pack, and thereby need not exceed the outer diameter of the remainder of the battery pack. The PCB and the other battery pack components may be substantially enveloped in a polyimide material. The components of the battery pack, including the PCB can arranged, sized and configured, such that they do not create protuberances in the enveloping material.

### CROSS-REFERENCE TO RELATED APPLICATIONS

This application claims priority to U.S. Provisional Application No. 62/383,789, filed Sep. 6, 2016, the contents of which are entirely incorporated by reference herein.

### BACKGROUND

This disclosure relates generally to battery packs, and in particular, to streamlined battery packs for use in compact electronic devices having interior housings that are at least partially cylindrical.

The use of battery-operated electronic devices, e.g., audio devices, smart phones, laptops, notebooks, and portable electronic devices continues to grow. Depending on the intended use of an electronic device, size of the device can be an important factor. For those electronic devices, which by their nature are preferably small, efficient use of internal housing space can be desirable. Most internal batteries in the field do little to foster efficient use of such internal housing space. There is thus room for improvement in the field.

### SUMMARY

This disclosure describes a streamlined battery pack. The battery pack includes a printed circuit board configured such that it adds only a minimal amount of volume to the battery pack and does not increase the width of the battery pack. The battery pack may be used in a variety of smaller electronic devices.

### BRIEF DESCRIPTION OF THE FIGURES

Implementations of the present application will now be described, by way of example only, with reference to the attached figures, wherein:

FIG. 1A illustrates a battery pack in accordance with some embodiments.

FIG. 1B illustrates an alternate view of a battery pack in accordance with some embodiments.

FIG. 1C illustrates a battery pack enveloped in a casing material in accordance with some embodiments.

FIG. 2 illustrates an enlarged portion of a front end of a battery pack in accordance with some embodiments.

FIG. 3 illustrates a side view of the area of the battery pack from FIG. 2.

FIG. 4A illustrates a circuit board and accompanying weld tabs in accordance with some embodiments.

FIG. 4B illustrates a circuit board in accordance with some embodiments.

FIG. 5 illustrates a layer of insulating material at a front end of a battery pack in accordance with some embodiments.

### DETAILED DESCRIPTION

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth to provide a thorough understanding of the implementations described herein. In other instances, methods, procedures and components have not been described in detail so as not to obscure the related relevant function being described. References to “an,” “one,” or “another” embodiment in this disclosure are not necessarily to the same or different embodiment, and they mean at least one. To be concise, a given figure may be used to illustrate the features of more than one embodiment, or more than one species of the disclosure, and not all elements in the figure may be required for any particular embodiment or species.

Several definitions that apply throughout this disclosure will now be presented. The word “coupled” is defined as connected, whether directly or indirectly through intervening components, and/or electromagnetically coupled, and is not necessarily limited to physical connections. A connection can be such that the objects are permanently connected or releasably connected as the context requires. The word “substantially” means almost completely, or strongly approaching. For example, a substantially smooth surface would be a surface which has a low friction coefficient and which is almost completely free of any bumps, dents or protrusions. Likewise, “substantially cylindrical” would refer to an object is close to being a cylinder and/or has the properties of a cylinder, but need not be perfectly cylindrical.

The present disclosure is directed to battery packs, and especially to battery packs that need to fit within small electronic devices, in which space is scarce. A battery pack can include multiple battery cells and/or multiple batteries collectively compartmentalized to serve as a power source for an electronic device, such as a portable audio device. An embodiment of this disclosure is a battery pack that includes at least two cylindrical cells located side by side. The outer sides of the cells form the sides of the battery pack. The battery pack can include a rightmost cell with a rightmost side, as well as a leftmost cell having a leftmost side. Each cell can have an upper side and a lower side, which can collectively form an upper side of the pack and a lower side of the pack. Each battery cell or battery can have a top and bottom. The top and bottom can have a height, which in the case of a circular top or bottom would be the diameter.

An embodiment of this disclosure is a battery pack containing cylindrical battery cells with a connector running along the length of the battery cells and nested between the battery cells to save space. The battery pack can include at least one circuit board, which may be a printed circuit board. The circuit board can be sized and arranged so as to minimize the amount of volume that the circuit board adds to the battery pack. The battery pack can also include a plurality of leads or egress wires, which may be connected to the circuit board at vias located along the perimeter of the circuit board. The leads and the connector may preferably not protrude beyond the sides of the battery cells.

The battery pack can be wrapped in a polyimide film or a plastic material that is substantially smooth and free of bumps, dimples and the like. Polyimide is a suitable material for creating such a surface. The battery pack can also be substantially sealed inside a polymer foil. The wrapping material can have small holes through which the leads pass.

At least one embodiment of this disclosure can include a printed circuit board configured for inclusion within a power unit for a portable electronic device. The printed circuit board can have an oblong body with a first planar surface and a second planar surface, with multiple edge-plated slots formed in the outline of the oblong body. The edge-plated slots can electrically couple a portion of the first planar surface and a portion of second planar surface. The perimeter of the oblong body can be smooth, except for the discontinuities created by the edge-plated slots. The printed circuit board can have various components on its surface, including a temperature monitor circuit and a battery-monitoring module. The temperature monitor can include a thermistor.

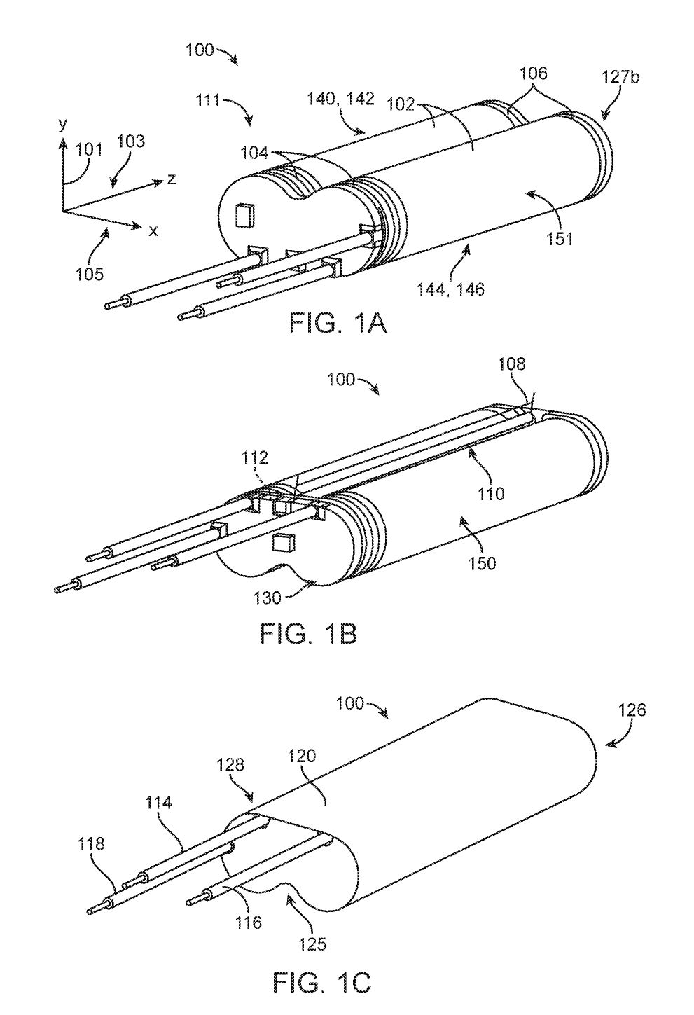

FIG. 1A illustrates a battery pack 100. The battery pack 100 includes two side-by-side cells 102 with each cell having a top 104 and a bottom 106. In the example illustrated, the battery cells are connected in parallel with one another, though in other embodiments the battery cells could be connected in series. Additionally, different numbers of battery cells could be used. The tops 104 of the battery cells 102 have poles of one polarity and the bottoms 106 of the battery cells 102 have poles of the opposite polarity. For series connections, the tops 104 and bottoms 106 would have alternating polarities. The battery cells 102 are cylindrical with the top 104 and bottom 106 of each cell connected by a sidewall extending in length 108 (see FIG. 1B) running in a direction of a Z-axis 103. The tops 104 and bottoms 106 are perpendicular to the Z-axis 103, lying in X-Y planes 101,103. The battery pack 100 includes a rightmost cell 140 and a leftmost cell 144. The rightmost cell 140 has a rightmost side 142, and the leftmost cell 144 has a leftmost side 146. The rightmost side 142 forms the right side 150 of the battery pack 100 (see FIG. 1B), and the leftmost side 146 forms the left side 151 of the battery pack 100. A layer of insulating material 127b can be seen near the bottom 106 of the battery cells 102. The bottoms 106 of the battery cells 102 can be coupled to one another, such as by being welded to the same piece of conductive material. The tops 104 of the battery cells 102 can likewise be coupled to one another.

FIG. 1B illustrates an alternate view of a battery pack 100, in which the battery pack 100 of FIG. 1A has been rotated 180 degrees along the Z-axis 103. A connector 110 is located interstitially between the battery cells 102 and runs along the length 108 of battery cells 102 from the bottom 106 of the battery cells to a circuit board 112, which is near the top 104 of the battery cells 102. As noted above, the circuit board 112 can be a printed circuit board, or can comprise a printed circuit board. The circuit board 112 has a front surface 130. As illustrated in FIG. 1A and FIG. 1B, the circuit board 112 is thin and adds little volume over that of the battery cells 102 themselves. Also, by comparing FIG. 1A and FIG. 1B, it can be seen that the circuit board 112 can be shaped so as to substantially conform to the shapes of the battery cells 102 and to the remainder of the battery pack 100 generally.

FIG. 1C illustrates a battery pack 100 enveloped in a casing material 120. The casing material can be made of polyimide tape or another suitable material. The battery pack 100 includes a first lead 114, which is coupled to the bottoms 106 of the battery cells 102 via the circuit board 112 and the connector 110, and thus has the same polarity as the bottoms 106 of the battery cells 106. In this example, the first lead 114 has a negative polarity. A second lead 116 is coupled to the tops 104 of the battery cells 102 via the circuit board 112, and hence has the same polarity at the tops 104. In the example show, a third lead 118 is connected to the circuit board 112. The third lead can be coupled to one or more components of the battery pack 100, including components that reside on the circuit board 112, such as for example a temperature monitoring circuit. Additional power and/or signal leads could also be provided depending on the specific details of a particular implementation. The battery pack 100 has a back end 126 near the insulating layer 127b (see FIG. 1A). The battery pack 100 has a front end 125 from which the leads 114, 116, 118 protrude through small through-holes 128 in the casing material 120. As shown in FIG. 1C, once the battery pack 100 is enveloped by the casing material 120, a very sleek design is evident. Notably, the outer surface of the battery pack 100 created by the casing material 120 is substantially smooth and substantially free of bumps, indentations, protrusions, and the like, i.e., substantially free of protuberances.

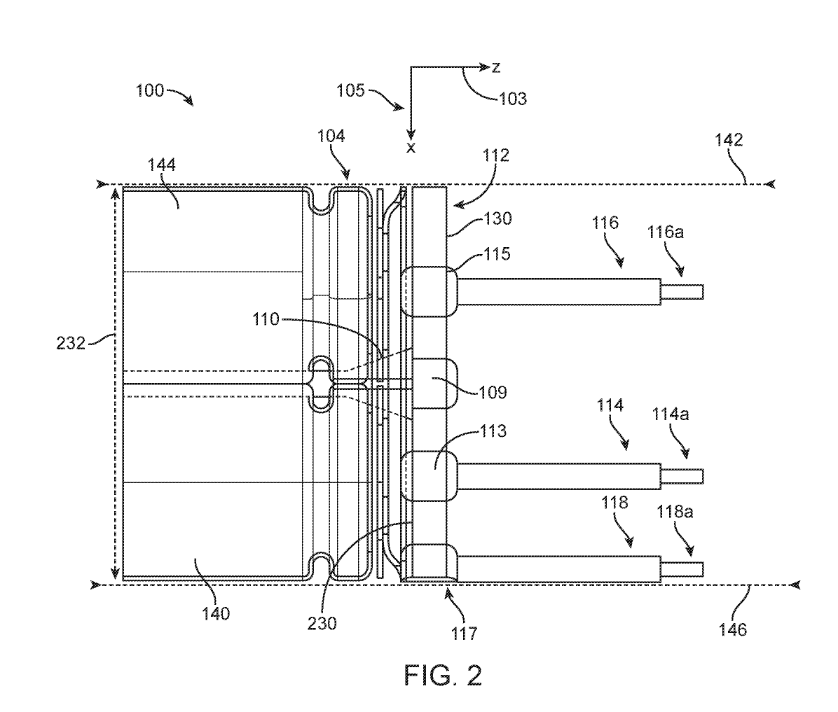

FIG. 2 illustrates a bottom plan view of the frontward end 125 of the battery pack 100. As can be seen from the figure, the circuit board 112 can be no wider than the distance 232 from the rightmost side 142 of the right side cell 140 to the leftmost side 146 of the left cell 144. Also, the leads (when laid straight as shown) need not protrude beyond the rightmost side. As shown, the connector 110 connects to the circuit board 112. The first lead 114 includes a first lead wire 114a. The second lead 116 includes a second lead wire 116a, and the third lead 118 includes a third lead wire 118a. The connector 110 includes a connective wire 110a (not shown). The connective wire 110a, the first lead wire 114a, the second lead wire 1161, and the third lead wire 118a are connected to the circuit board 112 at vias 109, 113, 115, and 117, respectively. In the example of FIG. 2, the tops 104 the battery cells 102 are circular and are located near the circuit board 112. The circuit board 112 has a rear surface 230, which lies parallel to the front surface 130. To be more precise, the front and rear surfaces 130, 230 form front and rear planes which are parallel to the X-Y plane (101, 105) and which are perpendicular to the connector 110 which runs parallel to the Z-axis 103.

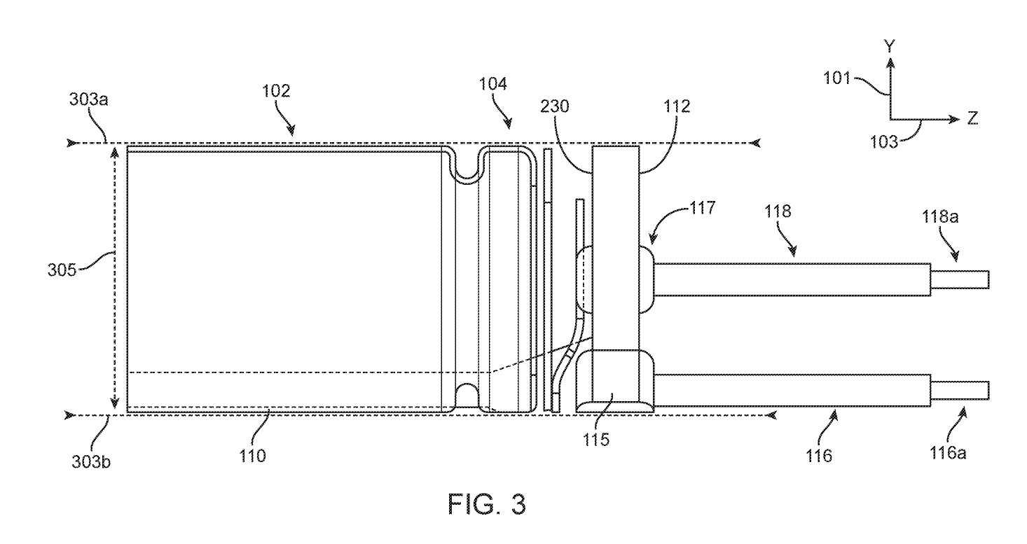

FIG. 3 illustrates a right side view of the area of the battery pack 100 from FIG. 2. As noted with regard to FIG. 2, first lead wire 116a is connected to the circuit board 112 at via (aka castellation) 115, and third lead wire 118a is connected to the circuit board 112 at via 117. For illustration purposes, the connector 110 can be seen through the right battery cell 140. The connector need not extend beyond the lower sides 303b of the battery cells 102. Indeed, in the illustrated embodiment, neither the leads 116, 118, nor the circuit board 112, extend beyond the upper sides 303a and the lower sides 303b in a direction of the Y-axis 105. The tops 104 of the cells 102, as well as the cells 102 themselves, have a height 305. The circuit board 112 can have the same height 305 or can have a height that is slightly shorter than the height 305 of the cells 102, so as to compensate for variations in placement of the circuit board 112 during manufacturing. The width of the circuit board can be narrower that distance 232 for the same reason.

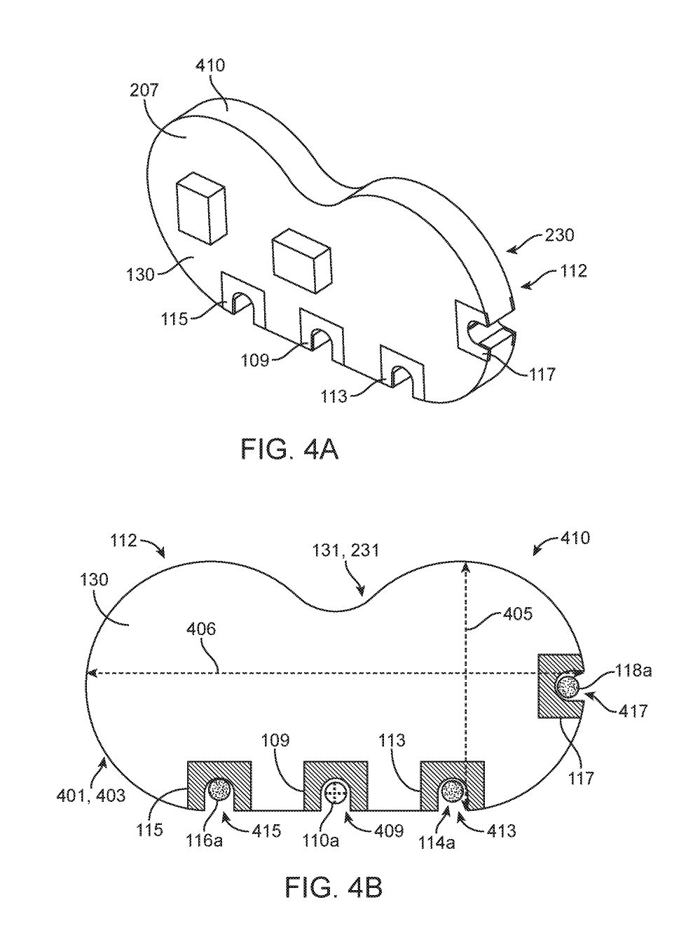

FIGS. 4A and 4B illustrate a circuit board 112 and accompanying weld tabs 401, 403. During manufacturing the weld tabs 401, 403 can be attached to the circuit board 112 in the unbent configuration shown. This right-angled shape of the weld tabs 401, 403 can provide room and line of sight during the time that the lead wires 114a, 116a, 118a, and the connective wire 110a are soldered to vias 113, 115, 117, and 109, respectively. The weld tabs 401, 403 can then be folded so as to fit between the rear surface 230 of the circuit board 112 and the tops 104 of the battery cells 102. (See FIGS. 2-3). As intimated above, the vias 113, 115, 117, 109 may be castellated vias. The vias 113, 115, 117, 109 may be made from copper and/or other suitable materials. The some or all of the vias may couple the front surface 130 to the rear surface 230, as well as to one or more components 207 on the circuit board 112. The front surface 130 and the rear surface 230 are separated by the perimeter 410, which runs around the outer boundary of the circuit board 112. In some implementations, the perimeter may be of uniform thickness as shown.

FIG. 4B illustrates an example of a front surface 130 of a circuit board 112. The rear surface 230 of the circuit board 112 is a mirror image of the front surface 130, and hence will not be described separately. In some embodiments, the widest portion 406 need be no wider that the distance from side 142 to side 146, that is, distance 406 does not exceed distance 232 (see FIG. 2). Likewise, the tallest portion of the circuit board 112 need be no taller than distance 305 (see FIG. 3) from the uppermost side 303a to the lowermost side 303b of the cells 102 in direction parallel to the Y-axis (see FIGS. 1A and 3). FIG. 4B shows cross-sectional views of the lead wires 114a, 116a, 118a, and connective wire 110a. First lead wire 114a is received within slot 413 of via 113, second lead wire 116a is received within slot 415 of via 115, lead wire 118a is received within slot 417 of via 117, and connective wire 110a is received within slot 409 of via 109. It will be noted that the cross-sectional areas of the wires 114a, 116a, 118a, and 110a are smaller than the slots in which they are received. Moreover, the slots are deep enough in the X-Y plane such than the diameters of the wires 114a, 116a, 118a, and 110a fit within the slots. The sizing and inset nature of the slots 49, 413, 415 and 417 may thus help ensure that the leads 114, 116 and 118, as well as connector 110 need not protrude outside the boundaries formed by the sides 150, 151, 303a, 303b of the battery cells 102. The front surface 130 of the circuit board 112 forms a front plane 401, and the rear surface 230 (see FIG. 4A) forms a rear plane 430, which in some implementations may be parallel to the front plane 401. The front surface 130 has an outline 131, and the rear surface 230 has an outline 231, both of which run the perimeter 410 of the circuit board 112. In some implementations, the outlines will be congruent and substantially correspond to the outline of the rest of the battery pack 100 when viewed from the front end 125 or the back end 126.

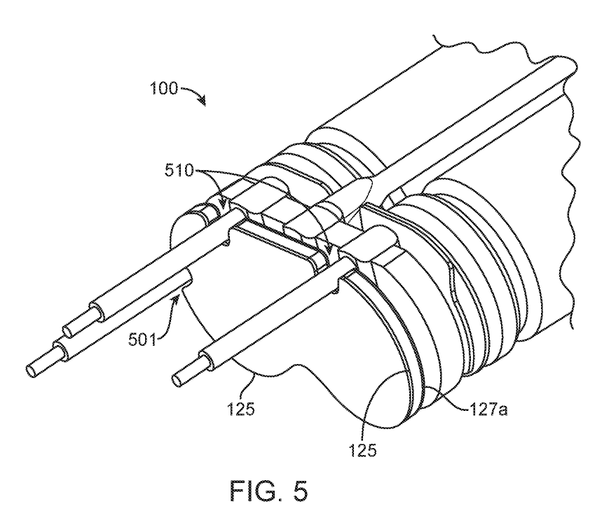

FIG. 5 illustrates a layer of insulating material 127a forming the front end 125 of the battery pack 100. Like the circuit board 112, the outline of the layer of insulating material 127a may conform generally to the shape and dimensions of the remainder of the battery pack 110. The layer 127a may include slots or spacings 501 through which the leads 114, 116, 118 pass.

The embodiments shown and described above are only examples. Even though numerous characteristics and advantages of the present technology have been set forth in the foregoing description, together with details of the structure and function of the present disclosure, the disclosure is illustrative only. Changes may be made in the detail, including in matters of shape, size and arrangement of the parts within the principles of the present disclosure up to, and including, the full extent established by the broad general meaning of the terms used in the claims.

What is claimed is:

1. A battery pack, the battery pack comprising a pack body which includes:
at least two side-by-side cells, including a right most cell having a rightmost side, and a leftmost cell having a leftmost side, each cell having an uppermost side, a lower most side, and a top and bottom with a sidewall running there-between, each top having a height, each cell having a first pole with a first polarity at the bottom and a second pole with a second polarity at the top, the first pole of each cell coupled to a connector interstitially located between the cells and running along their lengths, the connector including a connective wire;
a circuit board coupled to the connector, the circuit board having a front surface forming a front plane and a rear surface forming a rear plane, the front and rear surfaces bounded by a perimeter of the circuit board, the front surface having a maximal height no taller than the height of a cell top and a maximal width no wider than the distance from the rightmost side of the rightmost cell to the leftmost side of the leftmost cell; and
a first lead, a second lead, and a third lead connected to the circuit board at vias located along the perimeter of the circuit board,
wherein the leads and the connector do not protrude beyond the sides of the battery cells in a direction parallel to the front and rear planes of the circuit board along the perimeter.

2. The battery pack of claim 1, wherein the first lead comprises a first lead wire, the second lead comprises a second lead wire, and the third lead comprising a third lead wire; and
wherein each via comprises a slot inset along the perimeter, each slot nesting a respective wire therein, thereby preventing protrusion of the leads and connector beyond the sides of the battery cells.

3. The battery pack of claim 1, wherein the first lead wire is coupled via the circuit board to the connective wire so as to have the first polarity, the second lead wire is coupled to the second poles so as to have the second polarity, and the third lead wire is coupled to a circuit component on the circuit board.

4. The battery pack of claim 1, wherein the battery cells are cylindrical in shape and the heights of the battery cell tops are of the same length as the diameters of the battery cells.

5. The battery pack of claim 1, wherein the pack body is substantially enveloped in a polyimide film.

6. The battery pack of claim 5, wherein the polyimide film is substantially free of protuberances.

7. The battery pack of claim 1, wherein the pack body is substantially sealed inside a polymer foil.

8. The battery pack of claim 1, the battery pack further comprising: a front end and a back end, and wherein the circuit board is proximate the front end, the front end having an outline that is substantially congruent with that of the circuit board and that of the back end, and having perforated regions through which the leads pass.

9. The battery pack of claim 8, wherein the front end and the back end include regions composed of insulating material, and the front end contains gaps through which the leads pass.

10. The battery pack of claim 9, wherein the circuit board is no thicker than the insulating material of the front end.

11. The battery pack of claim 1, wherein the vias comprise copper.

12. The battery pack of claim 11, wherein the copper of the vias uniformly connects the front and back surfaces of the circuit board to one another.

13. The battery pack of claim 1, wherein the polarity of the interstitially located connective wire is negative.

14. The battery pack of claim 1, wherein the cells are connected in parallel with one another.

15. The battery pack of claim 1, wherein the front surface has a maximal height that is shorter than the height of a cell top and a maximal width that is not as wide as the distance from the rightmost side of the rightmost cell to the leftmost side of the leftmost cell.

16. A printed circuit board configured for inclusion within a power unit for a portable electronic device, the printed circuit board comprising:
an oblong body having a first planar surface and a second planar surface, the oblong body having an outline;
a plurality of edge-plated slots formed in the outline of the oblong body, electrically coupling a portion of the first planar surface and a portion of second planar surface, the edge-plated slots forming discontinuous regions in the outline,
wherein the outline of the oblong body is smooth except for the discontinuous regions formed by the edge-plated slots; and
wherein at least some of the edge-plated slots are configured such that wires connected thereto do not extend beyond any discontinuous portion in the outline.

17. The printed circuit board of claim 15, wherein a depth of at least one of the edge-plated slots in a direction parallel to the upper and lower surfaces is greater than a cross-sectional diameter of a wire received therein.

18. The printed circuit board of claim 15, the printed circuit board further comprising electrical one or more components on the front surface, wherein at least some of the wires are coupled to battery cells via the one or more components.

19. The printed circuit board of claim 18, wherein at least one of the one or more components is a temperature monitor.

20. The printed circuit board of claim 18, wherein the battery cells and the printed circuit board are covered by a polyimide cover having an outer surface substantially free of protuberances.
